(19) United States
(12) Patent Application Publication
(10) Pub. No.: US 2025/0337371 A1
(43) Pub. Date: Oct. 30, 2025

(54) ADJUSTMENT CIRCUIT

(71) Applicant: SMARTER MICROELECTRONICS (GUANG ZHOU) CO., LTD., Guangzhou (CN)

(72) Inventors: Yang HOU, Guangzhou (CN); Jun JIA, Guangzhou (CN)

(73) Assignee: SMARTER MICROELECTRONICS (GUANG ZHOU) CO., LTD., Guangzhou (CN)

(21) Appl. No.: 19/017,644

(22) Filed: Jan. 11, 2025

(30) Foreign Application Priority Data
Apr. 26, 2024 (CN) 202410515545.X

(51) Int. Cl. H03F 1/56; H03F 3/24

(52) U.S. Cl. CPC H03F 1/565; H03F 3/245; H03F 2200/387

(57) ABSTRACT

An adjustment circuit is connected to an output of a Power Amplifier (PA), and includes a sampling circuit, a first detector circuit, an impedance adjustment circuit, and an aperture tuning circuit. The sampling circuit is connected to the output of the PA, and is configured to sample a transmission signal and a reflection signal from the output of the PA, and output the sampled transmission signal and reflection signal. The first detector circuit is coupled to an output of the sampling circuit, and is configured to acquire the sampled transmission signal and reflection signal, and output a first detection signal according to a phase of the sampled transmission signal and a phase of the sampled reflection signal. The impedance adjustment circuit is connected to the first detector circuit, and is configured to adjust impedance according to the first detection signal, to reduce the reflection signal.

### CROSS-REFERENCE TO RELATED APPLICATION

The present application claims priority to Chinese Patent Application No. 202410515545.X filed on Apr. 26, 2024, the disclosure of which is hereby incorporated by reference in its entirety.

### BACKGROUND

In a mobile Radio Frequency (RF) terminal, matching between a Transmit-Receive (TR) module and an antenna greatly affects performance of the terminal, and the TR module mainly includes a transmission Power Amplifier (PA) and a receiver Low Noise Amplifier (LNA). In an actual application scenario, impedance of the antenna changes due to environmental effect, which is reflected as poor signal, increased power consumption, or the like in terms of user experience.

### SUMMARY

In view of this, embodiments of the disclosure provide an adjustment circuit.

The disclosure relates to the field of electronic technologies, and in particular to an adjustment circuit.

An embodiment of the disclosure provides an adjustment circuit, the adjustment circuit is connected to an output of a PA, and includes a sampling circuit, a first detector circuit, an impedance adjustment circuit, and an aperture tuning circuit. The sampling circuit is connected to the output of the PA, and is configured to sample a transmission signal and a reflection signal from the output of the PA, and output the sampled transmission signal and the sampled reflection signal. The first detector circuit is coupled to an output of the sampling circuit, and is configured to acquire the sampled transmission signal and the sampled reflection signal, and output a first detection signal according to a phase of the sampled transmission signal and a phase of the sampled reflection signal. The impedance adjustment circuit is connected to the first detector circuit, and is configured to adjust impedance according to the first detection signal, to reduce the reflection signal. The aperture tuning circuit is connected to the impedance adjustment circuit.

In some embodiments, the first detector circuit may include a first amplifier, and/or a second amplifier, and a mixing circuit. The first amplifier is coupled to the output of the sampling circuit, receives the sampled transmission signal, adjusts an amplitude of the sampled transmission signal, and outputs a first amplification signal. The second amplifier is coupled to the output of the sampling circuit, receives the sampled reflection signal, adjusts an amplitude of the sampled reflection signal, and outputs a second amplification signal. The mixing circuit is configured to acquire the first amplification signal or the sampled transmission signal, is also configured to acquire the second amplification signal or the sampled reflection signal, and performs mixing, to output the first detection signal.

In some embodiments, the first detector circuit may include the first amplifier and the second amplifier, the mixing circuit acquires the first amplification signal and the second amplification signal, here an amplitude of the first amplification signal is equal to that of the second amplification signal.

In some embodiments, the mixing circuit may include a mixer and a filter. The mixer is provided with a first end receiving the first amplification signal or the sampled transmission signal, and a second end receiving the second amplification signal or the sampled reflection signal, and the mixer outputs a mixing signal. The filter is provided with an input connected to the mixer and receiving the mixing signal, and an output coupled to the impedance adjustment circuit and outputting the first detection signal.

In some embodiments, the adjustment circuit may further include a second detector circuit, and the second detector circuit includes a first comparator. The first comparator is provided with an input coupled to the first detector circuit, and an output coupled to the impedance adjustment circuit, a first end of the first comparator receives the first amplification signal or the sampled transmission signal, a second end of the first comparator receives the second amplification signal or the sampled reflection signal, and the first comparator outputs a second detection signal according to an amplitude of the signal received by the first end and an amplitude of the signal received by the second end, the second detection signal is used by the impedance adjustment circuit to adjust the impedance.

In some embodiments, the output of the first comparator may also be connected to the first amplifier or the second amplifier, and a gain of the first amplifier or the second amplifier connected to the first comparator is adjustable, to form a feedback loop.

In some embodiments, the first detector circuit may include the first amplifier and the second amplifier, the mixing circuit acquires the first amplification signal and the second amplification signal, the first end of the first comparator receives the first amplification signal, the second end of the first comparator receives the second amplification signal, and the second detector circuit further includes a second comparator. The second comparator is provided with a first end receiving a reference signal, a second end connected to the first end or the second end of the first comparator and receiving the first amplification signal or the second amplification signal, and an output connected to the first amplifier or the second amplifier, and the second comparator is configured to adjust amplitudes of the first amplification signal and the second amplification signal.

In some embodiments, the adjustment circuit may further include a first turn-on circuit. The first turn-on circuit is provided with an input connected to an output of the first detector circuit, and an output connected to the impedance adjustment circuit, and the first turn-on circuit is configured to acquire the first detection signal and a first turn-on reference signal, so that the impedance adjustment circuit turns on or off adjustment of the impedance according to an output signal of the first turn-on circuit.

In some embodiments, the adjustment circuit may further include a second turn-on circuit. The second turn-on circuit is provided with an input connected to the second detector circuit, and an output connected to the impedance adjustment circuit, and the second turn-on circuit is configured to acquire the second detection signal and a second turn-on reference signal, so that the impedance adjustment circuit turns on or off adjustment of the impedance according to an output signal of the second turn-on circuit.

In some embodiments, the adjustment circuit may further include a processor circuit. The processor circuit is provided with an input connected to the first detector circuit, and an output connected to the impedance adjustment circuit, and the processor circuit is configured to adjust the impedance by the impedance adjustment circuit according to the first detection signal.

In some embodiments, the impedance adjustment circuit may preset multiple impedance combinations, and the impedance adjustment circuit adjusts the impedance by traversal and/or table lookup.

In some embodiments, the impedance adjustment circuit and the aperture tuning circuit may be integrated into the same module.

In some embodiments, the impedance adjustment circuit may include a first branch, a second branch, and a third branch. The first branch is provided with a first end connected to the sampling circuit, and a second end which is grounded. The second branch is provided with a first end connected to the aperture tuning circuit, and a second end which is grounded. The third branch is provided with a first end and a second end connected to the first end of the first branch and the first end of the second branch respectively.

In some embodiments, at least one of the first branch, the second branch or the third branch may be provided with multiple inductors and/or capacitors connected in parallel, and a switch is connected in series with at least one path of the parallel circuit.

In the embodiments of the disclosure, the adjustment circuit detects a state whether an output impedance of the PA is mismatched, including adjustment of the aperture tuning circuit and the impedance adjustment circuit, to tune aperture matching and impedance matching, optimize matching of the output impedance of the PA, and improve radiation efficiency of the transmission signal of the PA.

### BRIEF DESCRIPTION OF THE DRAWINGS

FIG. 1A is a first embodiment of a terminal device provided in the embodiments of the disclosure.

FIG. 1B is a second embodiment of the terminal device provided in the embodiments of the disclosure.

FIG. 2 is a first embodiment of an adjustment circuit provided in the embodiments of the disclosure.

FIG. 3 is a second embodiment of the adjustment circuit provided in the embodiments of the disclosure.

FIG. 4 is a third embodiment of the adjustment circuit provided in the embodiments of the disclosure.

FIG. 5 is a fourth embodiment of the adjustment circuit provided in the embodiments of the disclosure.

FIG. 6 is a fifth embodiment of the adjustment circuit provided in the embodiments of the disclosure.

FIG. 7 is a sixth embodiment of the adjustment circuit provided in the embodiments of the disclosure.

FIG. 8 is a seventh embodiment of the adjustment circuit provided in the embodiments of the disclosure.

FIG. 9 is an eighth embodiment of the adjustment circuit provided in the embodiments of the disclosure.

FIG. 10 is a ninth embodiment of the adjustment circuit provided in the embodiments of the disclosure.

FIG. 11 is a tenth embodiment of the adjustment circuit provided in the embodiments of the disclosure.

FIG. 12 is an eleventh embodiment of the adjustment circuit provided in the embodiments of the disclosure.

### DETAILED DESCRIPTION

The disclosure will be further described in detail below with reference to the drawings and embodiments. It should be understood that specific embodiments described below in the disclosure are only intended to explain the disclosure and are not intended to limit the disclosure.

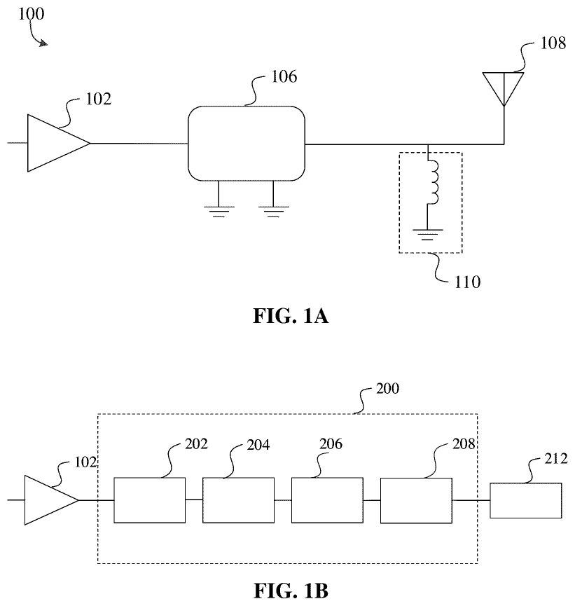

FIG. 1A is a first embodiment of a terminal device provided in the embodiments of the disclosure. With reference to FIG. 1A, the terminal device 100 includes a Power Amplifier (PA) 102, an adjustment circuit 106, and an antenna 108 connected in sequence; an output signal from an output of the PA 102 is transmitted to the antenna 108 through the adjustment circuit 106. The adjustment circuit 106 includes an impedance adjustment circuit and an aperture tuning circuit, and is configured to adjust impedance when impedance of the antenna 108 is affected, thereby reducing a reflection signal of the PA 102; for example, the impedance adjustment circuit and/or the aperture tuning circuit are adjusted in real time or at a fixed time, to improve mismatch.

In this embodiment, the terminal device 100 further includes an Electro-Static Discharge (ESD) 110. The ESD may also be omitted in other embodiments.

In some embodiments, the antenna may also be omitted.

In the disclosure, by detecting mismatch state of a path, it enables the adjustment circuit 106 to adjust the impedance, for example, tune aperture matching and impedance matching in real time or at a fixed time, to optimize radiation efficiency of the antenna 108 and matching between the antenna 108 and the PA 102, thereby improving Radio Frequency (RF) performance and user experience of the terminal device 100.

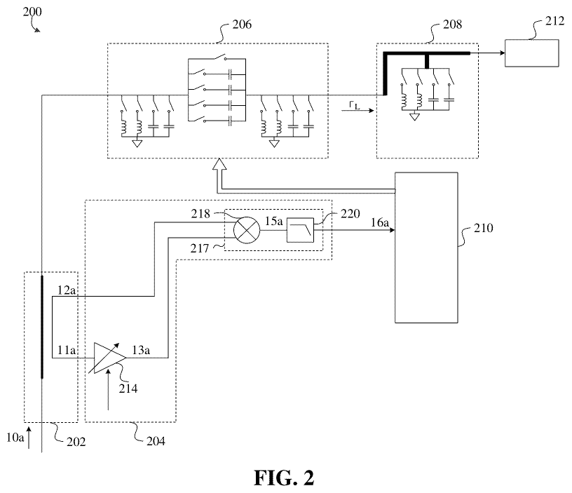

In some embodiments of the disclosure, with reference to FIG. 1B, an adjustment circuit 200 is provided, the adjustment circuit 200 is connected to the output of the PA 102, and includes a sampling circuit 202, a first detector circuit 204, an impedance adjustment circuit 206, and an aperture tuning circuit 208. The sampling circuit 202 is connected to the output of the PA, and is configured to sample a transmission signal and a reflection signal from the output of the PA, and output the sampled transmission signal and the sampled reflection signal. The first detector circuit 204 is coupled to an output of the sampling circuit 202, and is configured to acquire the sampled transmission signal and the sampled reflection signal, and output a first detection signal according to a phase of the sampled transmission signal and a phase of the sampled reflection signal. The impedance adjustment circuit 206 is connected to the first detector circuit 204, and is configured to adjust impedance according to the first detection signal, to reduce the reflection signal. The aperture tuning circuit 208 is connected to the impedance adjustment circuit 206. In some embodiments, the output signal from the output of the PA 102 (it may be understood as an output signal 10a in FIG. 2 to FIG. 12) may be a RF signal. In some embodiments, an antenna 212 may also be omitted.

When impedance of the path is mismatched, the impedance may be adjusted by the impedance adjustment circuit 206; or, the impedance may be adjusted by the impedance adjustment circuit 206 and the aperture tuning circuit 208 together, to enable the mismatched impedance to be matched again, so that the impedance may be dynamically adjusted, thereby reducing the reflection signal and improving the antenna efficiency. Adjustment of the impedance adjustment circuit and adjustment of the aperture tuning circuit are not divided into primary adjustment and secondary adjustment, and each of the two adjustments may be primary adjustment; or, one of the two adjustments may be primary adjustment, and another one of the two adjustments may be fine adjustment, which is not limited here. It should be noted that when bands are switched, the impedance may also be adjusted by the adjustment circuit 200, to make it applicable to different bands.

It should be noted that the aperture tuning circuit may perform adjustment according to an output signal from the sampling circuit and/or the detector circuit, that is, the aperture tuning circuit may perform adjustment according to the sampling signal or the detection signal, which is not limited here.

In some embodiments, with reference to FIG. 2 to FIG. 12, the sampling circuit 202 includes a coupler, the coupler is connected to the output of the PA, samples the transmission signal and the reflection signal from the output of the PA, and outputs the sampled transmission signal 11a and the sampled reflection signal 12a. A number of couplers may be selected according to requirements, and the two signals may be acquired by one coupler or two couplers. It should be noted that sampling parameters of the couplers may be the same or different, which is not limited here. For example, a coupling degree of the transmission signal may be the same as or different from that of the reflection signal. For another example, the coupling degree of the reflection signal is greater than that of the transmission signal.

In some embodiments, with reference to FIG. 2 to FIG. 12, the first detector circuit 204 receives the sampled transmission signal 11a and the sampled reflection signal 12a, detects an amplitude of the sampled transmission signal 11a and a phase of the sampled reflection signal 12a, and outputs a first detection signal 16a; the first detection signal 16a is configured to determine whether the impedance is mismatched.

In some embodiments, the first detector circuit includes a first amplifier, and/or a second amplifier, and a mixing circuit. The first amplifier is coupled to the output of the sampling circuit, receives the sampled transmission signal, adjusts an amplitude of the sampled transmission signal, and outputs a first amplification signal. The second amplifier is coupled to the output of the sampling circuit, receives the sampled reflection signal, adjusts an amplitude of the sampled reflection signal, and outputs a second amplification signal. The mixing circuit is configured to acquire the first amplification signal and the sampled reflection signal, acquire the sampled transmission signal and the second amplification signal, or acquire the first amplification signal and the second amplification signal, and performs mixing, to output the first detection signal. That is, the first detector circuit may include one or more amplifiers to adjust the sampling signal.

In some embodiments, with reference to FIG. 2, the first detector circuit 204 includes a first amplifier 214 and a mixing circuit 217. The first amplifier 214 is coupled to the output of the sampling circuit 202, receives the sampled transmission signal 11a, amplifies the sampled transmission signal 11a, adjusts an amplitude of the sampled transmission signal 11a, and outputs a first amplification signal 13a. The mixing circuit 217 is configured to acquire the first amplification signal 13a and the sampled reflection signal 12a, and performs mixing, to output the first detection signal 16a.

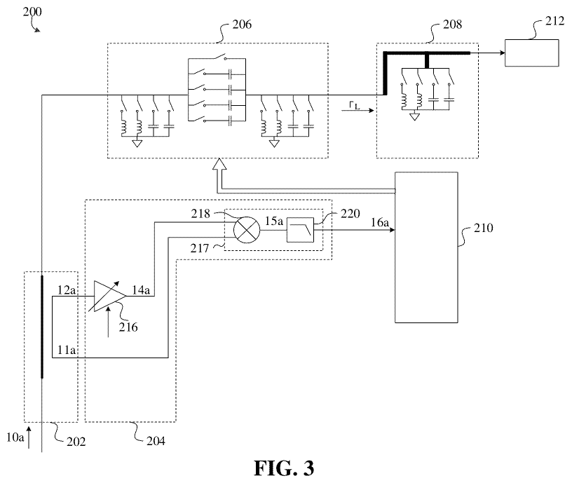

In some embodiments, with reference to FIG. 3, the first detector circuit 204 includes a second amplifier 216 and a mixing circuit 217. The second amplifier 216 is coupled to the output of the sampling circuit 202, receives the sampled reflection signal 12a, amplifies the sampled reflection signal 12a, adjusts an amplitude of the sampled reflection signal 12a, and outputs a second amplification signal 14a. The mixing circuit 217 is configured to acquire the sampled transmission signal 11a and the second amplification signal 14a, and performs mixing, to output the first detection signal 16a.

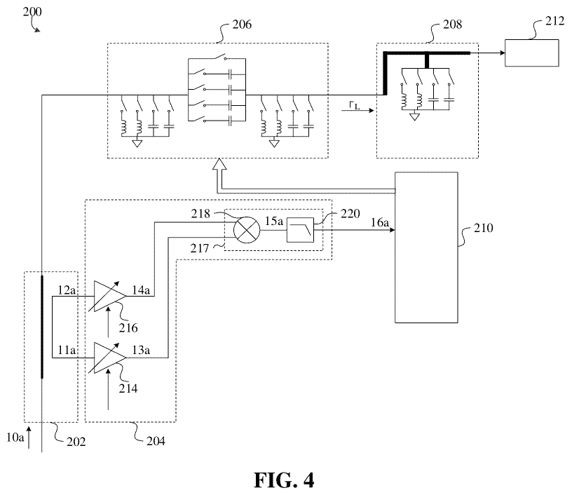

In some embodiments, with reference to FIG. 4, the first detector circuit 204 includes a first amplifier 214, a second amplifier 216, and a mixing circuit 217. The first amplifier 214 is coupled to the output of the sampling circuit 202, receives the sampled transmission signal 11a, amplifies the sampled transmission signal 11a, adjusts an amplitude of the sampled transmission signal 11a, and outputs a first amplification signal 13a. The second amplifier 216 is coupled to the output of the sampling circuit 202, receives the sampled reflection signal 12a, amplifies the sampled reflection signal 12a, adjusts an amplitude of the sampled reflection signal 12a, and outputs a second amplification signal 14a. The mixing circuit 217 is configured to acquire the first amplification signal 13a and the second amplification signal 14a, and performs mixing, to output the first detection signal 16a.

In some embodiments, the first amplifier and/or the second amplifier is an amplifier with adjustable parameter, which may adjust amplitudes of signals according to parameters such as band or the like, to adjust amplitudes of input signals of the mixing circuit. Exemplarily, with reference to FIG. 4, each of the first amplifier 214 and the second amplifier 216 is an adjustable amplifier, the first amplifier 214 may amplify the sampled transmission signal 11a in different bands, and the second amplifier 216 may amplify the sampled reflection signal 12a in different bands, to increase a bandwidth of the mixing circuit 217. In other embodiments, the first amplifier and/or the second amplifier may also be an amplifier with fixed parameters.

In some embodiments, amplitudes of the input signals of the mixing circuit may be set according to requirements, so that they may be mixed at a preset ratio. For example, amplitudes of two input signals of the mixing circuit are equal; for another example, after adjustment by the amplifier, the amplitude of the signal in the path of the sampled transmission signal is 0.5 to 1.5 times the amplitude of the signal in the path of the sampled reflection signal. It may also be understood that the amplitude of the first amplification signal or the sampled transmission signal and the amplitude of the second amplification signal or the sampled reflection signal acquired by the mixing circuit may be equal or in other ratios.

In some embodiments, an amplitude of the first amplification signal 13a is equal to that of the sampled reflection signal 12a, an amplitude of the sampled transmission signal 11a is equal to that of the second amplification signal 14a, or the amplitude of the first amplification signal 13a is equal to that of the second amplification signal 14a, and the signals are input to the mixing circuit 217. The mixing circuit 217 receives signals with equal amplitude. During mixing, a residual direct current is irrelevant to amplitudes of the signals, thereby simplifying the design.

In some embodiments, the first amplifier and/or the second amplifier is a multi-stage amplifier including multiple amplifiers connected in sequence, to amplify the signal multiple times. In other embodiments, the first amplifier and/or the second amplifier may also be a single-stage amplifier.

In some embodiments, there may also be multiple first amplifiers and/or multiple second amplifiers, and multiple amplifiers have different parameters respectively and may be switched according to parameters such as band of the RF signal, etc.

In some embodiments, with reference to FIG. 2 to FIG. 12, the mixing circuit 217 includes a mixer 218 and a filter 220. The mixer 218 is provided with a first end receiving the first amplification signal 13a or the sampled transmission signal 11a, and a second end receiving the second amplification signal 14a or the sampled reflection signal 12a, and the mixer 218 outputs a mixing signal 15a. The filter 220 is provided with an input connected to the mixer 218 and receiving the mixing signal 15a, and an output coupled to the impedance adjustment circuit 206 and outputting the first detection signal 16a.

In some embodiments, the filter 220 is configured to filter high-frequency signals and output a stable first detection signal 16a. The first detection signal 16a is configured to adjust impedance and/or phase of the impedance adjustment circuit 206.

In some embodiments, the adjustment circuit further includes a second detector circuit, and the second detector circuit includes a first comparator. The first comparator is provided with an input coupled to the first detector circuit, and an output coupled to the impedance adjustment circuit, a first end of the first comparator receives the first amplification signal or the sampled transmission signal, a second end of the first comparator which receives the second amplification signal or the sampled reflection signal, and the first comparator outputs a second detection signal according to an amplitude of the signal received by the first end and an amplitude of the signal received by the second end, the second detection signal is used by the impedance adjustment circuit to adjust the impedance. In this way, impedance mismatch is adjusted according to the phase and amplitude, which may further improve signal transmission efficiency and reduce loss.

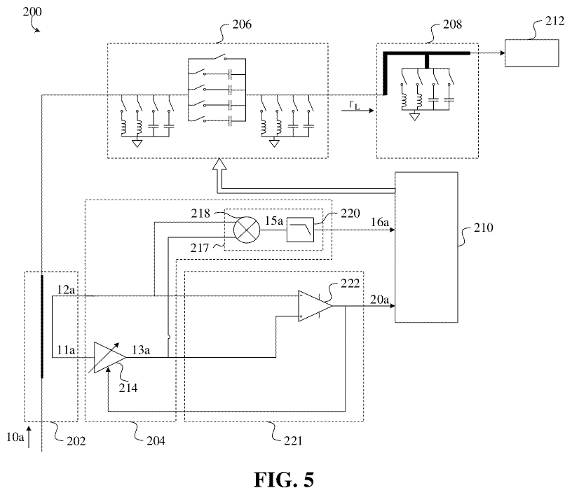

In some embodiments, with reference to FIG. 5, the second detector circuit 221 includes a first comparator 222. The first comparator 222 is provided with an output coupled to the impedance adjustment circuit 206, a first end receiving the first amplification signal 13a, and a second end receiving the sampled reflection signal 12a, and the first comparator 222 outputs a second detection signal 20a, the second detection signal 20a is used by the impedance adjustment circuit 206 to adjust the impedance.

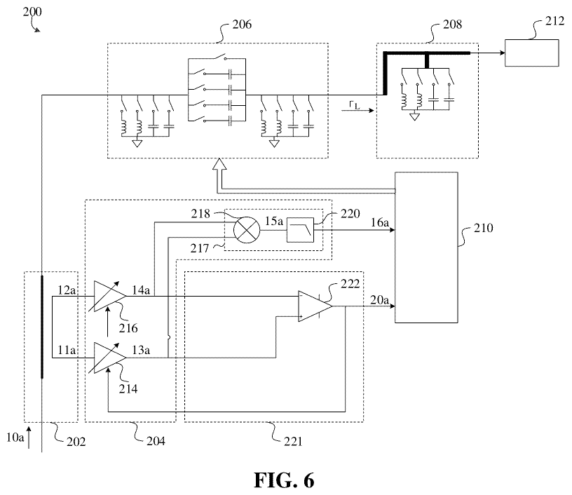

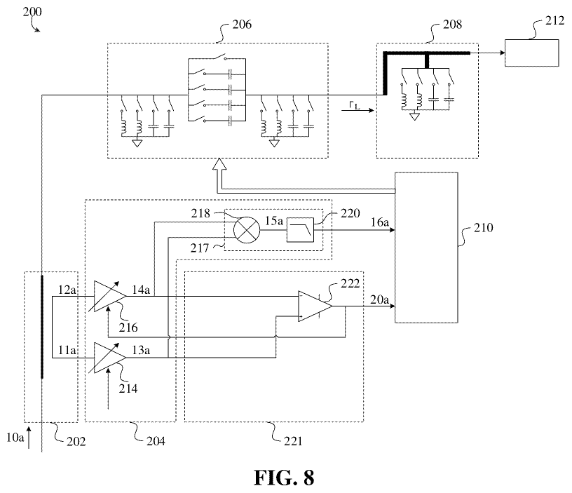

In some embodiments, with reference to FIG. 6 or FIG. 8, the second detector circuit 221 includes a first comparator 222. The first comparator 222 is provided with an output coupled to the impedance adjustment circuit 206, a first end receiving the first amplification signal 13a, and a second end receiving the second amplification signal 14a, and the first comparator 222 outputs a second detection signal 20a, the second detection signal 20a is used by the impedance adjustment circuit 206 to adjust the impedance.

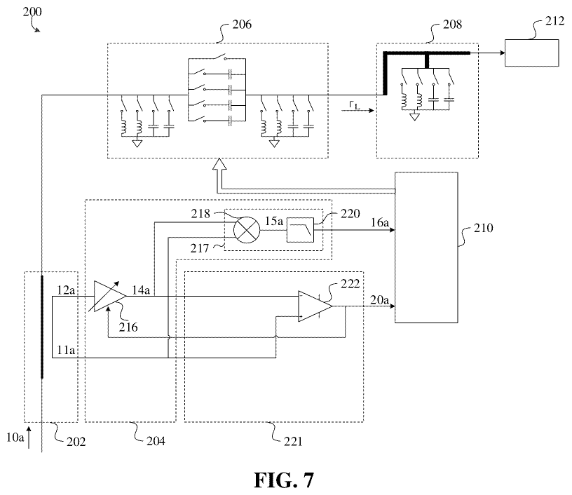

In some embodiments, with reference to FIG. 7, the second detector circuit 221 includes a first comparator 222. The first comparator 222 is provided with an output coupled to the impedance adjustment circuit 206, a first end receiving the sampled transmission signal 11a, and a second end receiving the second amplification signal 14a, and the first comparator 222 outputs a second detection signal 20a, the second detection signal 20a is used by the impedance adjustment circuit 206 to adjust the impedance.

In some embodiments, the first amplifier and/or the second amplifier is an adjustable amplifier, and the output of the first comparator is also connected to the first amplifier or the second amplifier, to form a feedback loop, thereby adjusting the amplitude of the first amplification signal and/or the amplitude of the second amplification signal.

For example, in FIG. 5 and FIG. 6, the output of the first comparator 222 is also connected to the first amplifier, to adjust the amplitude of the first amplification signal. For another example, in FIG. 7 and FIG. 8, the output of the first comparator 222 is also connected to the second amplifier, to adjust the amplitude of the second amplification signal.

In some embodiments, with reference to FIG. 6 or FIG. 8, when one of the first amplifier and the second amplifier forms a feedback loop with the comparator, another one of the first amplifier and the second amplifier may be an amplifier with fixed parameters, and amplitudes of the two amplifiers are adjusted by only one amplifier.

In some embodiments, with reference to FIG. 6 or FIG. 8, when one of the first amplifier and the second amplifier forms a feedback loop with the comparator, another one of the first amplifier and the second amplifier adjusts amplitudes thereof by acquiring a control signal, here the control signal is generated based on the second detection signal.

In some embodiments, the second detector circuit further includes a second comparator. The second comparator is provided with a first end receiving a reference signal, a second end connected to the first end or the second end of the first comparator and receiving the first amplification signal or the second amplification signal, and an output connected to the first amplifier or the second amplifier, and the second comparator is configured to adjust amplitudes of the first amplification signal and the second amplification signal.

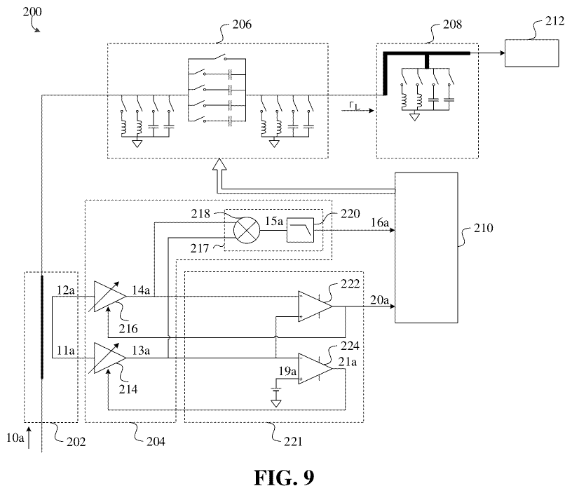

In some embodiments, with reference to FIG. 9, the first detector circuit 204 includes a first amplifier 214 and a second amplifier 216, and the second detector circuit includes a first comparator 222 and a second comparator 224. The first comparator 222 is provided with a feedback loop leading to the second amplifier 216, to adjust the amplitude of the sampled reflection signal 12a, and the second comparator 224 is provided with a feedback loop leading to the first amplifier 214, to adjust the amplitude of the sampled transmission signal 11a. Exemplarily, after each of the first comparator 222 and the second comparator 224 is stable, each of the second amplification signal 14a and the first amplification signal 13a is the same as a comparison signal 21a, so that the amplitude of the second amplification signal 14a is the same as that of the first amplification signal 13a, and the two signals are input to the mixing circuit 217. The mixing circuit 217 receives signals with equal amplitude. In some embodiments, a reference signal 19a is set according to a Voltage Standing Wave Ratio (VSWR).

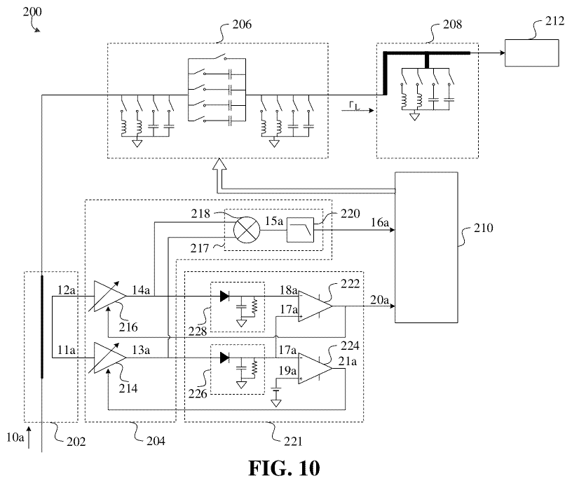

In some embodiments, with reference to FIG. 10, the second detector circuit 221 further includes a first detection circuit 226 and a second detection circuit 228. The first detection circuit 226 is coupled to an output of the first amplifier 214, is configured to rectify the first amplification signal, and is provided with an output outputting a first rectification signal 17a. The second detection circuit 228 is coupled to an output of the second amplifier 216, is configured to rectify the second amplification signal, and is provided with an output outputting a second rectification signal 18a. In other embodiments, only the first detection circuit or the second detection circuit may be provided.

In some embodiments, with reference to FIG. 10, the first detection circuit 226 and/or the second detection circuit 228 include a diode, an inductor and a capacitor. An input of the diode is coupled to the output of the first amplifier 214, an output of the diode is coupled to a first end of the inductor and a first end of the capacitor, and a second end of the inductor and a second end of the capacitor are grounded, to rectify the first amplification signal.

In some embodiments, the adjustment circuit further includes a first turn-on circuit. The first turn-on circuit is provided with an input connected to an output of the first detector circuit, and an output connected to the impedance adjustment circuit, and the first turn-on circuit is configured to acquire the first detection signal and a first turn-on reference signal, so that the impedance adjustment circuit turns on or off adjustment of the impedance according to an output signal of the first turn-on circuit.

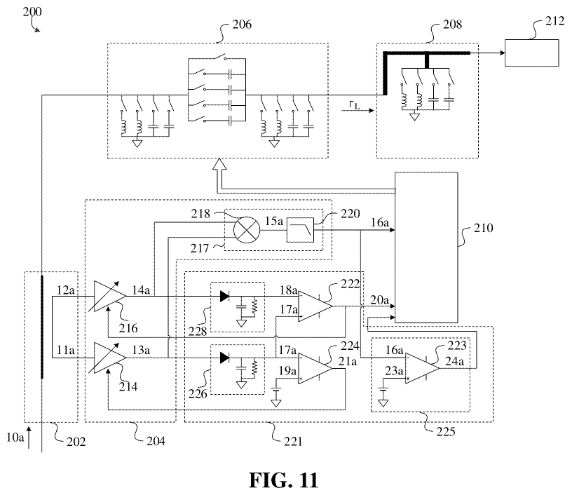

In some embodiments, with reference to FIG. 11, the first turn-on circuit 225 includes a third comparator 223. The third comparator 223 is provided with a first end receiving a first turn-on reference signal 23a, and a second end receiving the first detection signal 16a, the third comparator 223 compares the first turn-on reference signal 23a with the first detection signal 16a, and outputs a first comparison signal 24a. The impedance adjustment circuit 206 turns on or off adjustment of the impedance according to the first comparison signal, and after turning off adjustment of the impedance, the first detection signal 16a and/or the second detection signal 20a are not acquired any more. In some embodiments, the first turn-on reference signal 23a is set according to VSWR.

In some embodiments, the adjustment circuit further includes a second turn-on circuit. The second turn-on circuit is provided with an input connected to the second detector circuit, and an output connected to the impedance adjustment circuit, and the second turn-on circuit is configured to acquire the second detection signal and a second turn-on reference signal, so that the impedance adjustment circuit turns on or off adjustment of the impedance according to an output signal of the second turn-on circuit.

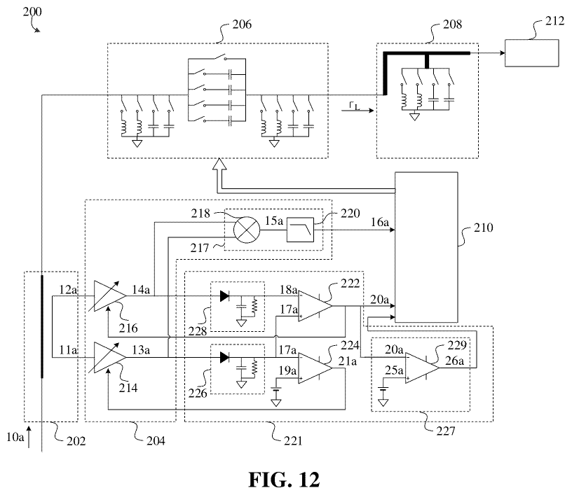

In some embodiments, with reference to FIG. 12, the second turn-on circuit 227 includes a fourth comparator 229. The fourth comparator 229 is provided with a first end receiving a second turn-on reference signal 25a, and a second end receiving the second detection signal 20a, the fourth comparator 229 compares the second turn-on reference signal 25a with the second detection signal 20a, and outputs a second comparison signal 26a. The impedance adjustment circuit 206 turns on or off adjustment of the impedance according to the second comparison signal, and after turning off adjustment of the impedance, acquisition of the first detection signal 16a and/or the second detection signal 20a is stopped. In some embodiments, the second turn-on reference signal 25a is set according to VSWR.

In some embodiments, the impedance adjustment circuit presets multiple impedance combinations, and the impedance adjustment circuit adjusts the impedance by traversal and/or table lookup. Table lookup or traversal information includes information of multiple preset impedance combinations of the impedance adjustment circuit 206.

In some embodiments, the table lookup and traversal may be performed simultaneously or separately; and the two adjustments may perform primary adjustment on the impedance, or may perform fine adjustment on the impedance, or the fine adjustment may not be required. For example, the impedance adjustment circuit performs the primary adjustment by traversal, and then performs the fine adjustment by table lookup; for another example, the impedance adjustment circuit performs the primary adjustment by table lookup, and then performs the fine adjustment by traversal; for another example, the primary adjustment and the fine adjustment are performed by traversal or table lookup; for another example, the adjustment is performed by traversal or table lookup.

In some embodiments, when mismatch of transmission impedance is determined according to the first detection signal and/or the second detection signal, the impedance adjustment circuit 206 turns on adjustment of the impedance and adjusts the impedance according to the first detection signal and/or the second detection signal, and a Look-Up-Table (LUT) from the table lookup information. The LUT includes information of multiple preset impedance combinations of the impedance adjustment circuit 206 and information of mismatched impedance, and a suitable impedance combination is selected according to the information of mismatched impedance.

In some embodiments, when the impedance is adjusted by traversal, the impedance adjustment circuit 206 is adjusted to the preset impedance combinations in sequence, and after each adjustment, a situation whether the output impedance of the PA is mismatched is determined, until the second detection signal is in a non-mismatch range, and adjustment of the impedance adjustment circuit 206 is stopped.

In some embodiments, the impedance adjustment circuit includes six to twelve impedance combinations, and the mismatched impedance in a range of VSWR 3:1 to 10:1 may be adjusted to be less than VSWR 2.5:1 through adjustment of the impedance. For example, the impedance adjustment circuit includes eight impedance combinations; for another example, the mismatched impedance is adjusted to be VSWR 1.5:1, 2:1, etc.

In some embodiments, the impedance combinations may correspond to designated information bands respectively, for example, each of high/medium/low frequencies has at least three impedance combinations.

In some embodiments, with reference to one of FIG. 2 to FIG. 12, the impedance adjustment circuit 206 includes a first branch, a second branch, and a third branch. The first branch is provided with a first end connected to the sampling circuit, and a second end which is grounded. The second branch is provided with a first end connected to the aperture tuning circuit, and a second end which is grounded. The third branch is provided with a first end and a second end connected to the first end of the first branch and the first end of the second branch respectively.

In some embodiments, at least one of the first branch, the second branch or the third branch is provided with multiple inductors and/or capacitors connected in parallel, and a switch is connected in series with at least one path of the parallel circuit. For example, as shown in FIG. 3, each of the first branch, the second branch and the third branch includes two inductors connected in parallel and two capacitors connected in parallel, and each parallel component is connected in series with a switch, so that it may be adjusted.

In some embodiments, the impedance adjustment circuit includes one or more x-type three-element impedance matching circuits, which may also be understood as the impedance adjustment circuit including a single-stage or multi-stage matching impedance. In some embodiments, a x-type three-element impedance matching circuit may be formed of one inductor and two capacitors, or, of one capacitor and two inductors.

In some embodiments, the inductor in an impedance matching circuit may be set as an adjustable inductor, and/or, the capacitor in an impedance matching circuit may be set as an adjustable capacitor, to enable the impedance matching circuit to adjust impedance conversion according to different RF signals. For example, impedance conversion adjustment may be performed on signals in different bands.

In some embodiments, with reference to one of FIG. 2 to FIG. 12, the impedance adjustment circuit 206 and the aperture tuning circuit 208 are integrated into the same module. In this way, requirements of important indices such as low cost, miniaturization or the like of the adjustment circuit may be met. In other embodiments, the impedance adjustment circuit 206 and the aperture tuning circuit 208 may also be located in different modules respectively.

In some embodiments, with reference to FIG. 5 to FIG. 12, the adjustment circuit further includes a processor circuit 210. The processor circuit 210 is provided with an input connected to the first detector circuit and the second detector circuit, and an output connected to the impedance adjustment circuit, and the processor circuit 210 is configured to adjust the impedance by the impedance adjustment circuit according to the first detection signal and the second detection signal. When the adjustment circuit omits the second detector circuit, with reference to FIG. 2 to FIG. 4, the processor circuit is connected to the first detector circuit.

It should be noted that signal processing and control in the above embodiments may be achieved by the processor circuit, for example, comparison of the first detection signal with a preset value, table lookup or other manners are used to control adjustment of the impedance, adjust a gain of the first amplifier and/or a gain of the second amplifier, or the like, which are not elaborated here.

In some embodiments, the processor circuit 210 includes a memory circuit, the memory circuit is configured to store a preset impedance; the processor circuit is also configured to adjust the impedance by the impedance adjustment circuit 206 according to the preset impedance. In some embodiments, the memory circuit may be a Random Access Memory (RAM).

It should be noted that components/circuits in the above embodiments may be applied to other embodiments, which is not limited in the disclosure; components/circuits used for impedance matching (such as the impedance adjustment circuit 206) may be fully or partially set as adjustable structures.

In several embodiments provided in the disclosure, it should be understood that the disclosed devices and methods may be implemented in other manners. The device embodiments as described above are only schematic, and for example, division of the units is only a logic function division, and there may be other division manners in actual implementations. For example, multiple units or components may be combined or integrated into another system, or some features may be omitted or may not be executed. Furthermore, coupling or direct coupling or communication connection between displayed or discussed components may be indirect coupling or communication connection implemented through some interfaces, of the device or the units, and may be electrical, mechanical or use other forms.

The above units described as separate components may be or may not be physically separated, and components displayed as units may be or may not be physical units, that is, may be located in a place, or may be distributed to multiple network units. Part or all of the units may be selected to achieve the purpose of the solutions in the embodiments according to actual requirements.

Furthermore, each functional unit in the embodiments of the disclosure may be integrated into a processing unit, or each unit may be separately used as a unit, or two or more than two units may be integrated into a unit. The above integrated unit may be implemented in form of hardware or in form of hardware plus software functional units.

It may be understood that “one embodiment” or “an embodiment” mentioned throughout the description means that specific features, structures or characteristics related to the embodiment are included in at least one embodiment of the disclosure. Therefore, “in one embodiment” or “in an embodiment” present throughout the description does not necessarily refer to the same embodiment. Furthermore, these specific features, structures or characteristics may be combined in one or more embodiments in any suitable manner. It should be understood that in various embodiments of the disclosure, sizes of serial numbers of the above processes do not mean a sequence of execution, and the sequence of execution of each process should be determined by its function and internal logic, and should not constitute any limitation on implementation processes of the embodiments of the disclosure. The above serial numbers of the embodiments of the disclosure are only for the purpose of descriptions, and do not represent advantages and disadvantages of the embodiments.

It should be noted that terms “including”, “include” or any other variants thereof in the context are intended to encompass a non-exclusive inclusion, so that a process, method, article or apparatus including a series of elements includes not only those elements, but also other elements which are not explicitly listed, or elements inherent to such process, method, article or apparatus. Without further limitation, an element defined by a statement “including a . . . ” does not preclude presence of additional identical elements in a process, method, article or apparatus including the element.

The above descriptions are only implementations of the disclosure, however, the scope of protection of the disclosure is not limited thereto. Variation or replacement easily conceived by any technician familiar with this technical field within the technical scope disclosed in the disclosure, should fall within the scope of protection of the disclosure.

We claim:

1. An adjustment circuit, connected to an output of a Power Amplifier (PA), the adjustment circuit comprising:
a sampling circuit, connected to the output of the PA, and configured to sample a transmission signal and a reflection signal from the output of the PA, and output the sampled transmission signal and the sampled reflection signal;
a first detector circuit, coupled to an output of the sampling circuit, and configured to acquire the sampled transmission signal and the sampled reflection signal, and output a first detection signal according to a phase of the sampled transmission signal and a phase of the sampled reflection signal;
an impedance adjustment circuit, connected to the first detector circuit, and configured to adjust impedance according to the first detection signal, to reduce the reflection signal; and
an aperture tuning circuit, connected to the impedance adjustment circuit.

2. The adjustment circuit of claim 1, wherein the first detector circuit comprises:
a first amplifier, coupled to the output of the sampling circuit, receiving the sampled transmission signal, adjusting an amplitude of the sampled transmission signal, and outputting a first amplification signal; and/or
a second amplifier, coupled to the output of the sampling circuit, receiving the sampled reflection signal, adjusting an amplitude of the sampled reflection signal, and outputting a second amplification signal; and
a mixing circuit, configured to acquire the first amplification signal or the sampled transmission signal, also configured to acquire the second amplification signal or the sampled reflection signal, and performing mixing, to output the first detection signal.

3. The adjustment circuit of claim 2, wherein the first detector circuit comprises the first amplifier and the second amplifier, the mixing circuit acquires the first amplification signal and the second amplification signal, and wherein an amplitude of the first amplification signal is equal to that of the second amplification signal.

4. The adjustment circuit of claim 2, wherein the mixing circuit comprises:
a mixer, provided with a first end receiving the first amplification signal or the sampled transmission signal, and a second end receiving the second amplification signal or the sampled reflection signal, and outputting a mixing signal; and
a filter, provided with an input connected to the mixer and receiving the mixing signal, and an output coupled to the impedance adjustment circuit and outputting the first detection signal.

5. The adjustment circuit of claim 2, wherein the adjustment circuit further comprises a second detector circuit, and the second detector circuit comprises:
a first comparator, provided with an input coupled to the first detector circuit, and an output coupled to the impedance adjustment circuit, a first end of the first comparator receiving the first amplification signal or the sampled transmission signal, a second end of the first comparator receiving the second amplification signal or the sampled reflection signal, and the first comparator outputting a second detection signal according to an amplitude of the signal received by the first end and an amplitude of the signal received by the second end, the second detection signal used by the impedance adjustment circuit to adjust the impedance.

6. The adjustment circuit of claim 5, wherein the output of the first comparator is also connected to the first amplifier or the second amplifier, and a gain of the first amplifier or the second amplifier connected to the first comparator is adjustable, to form a feedback loop.

7. The adjustment circuit of claim 5, wherein the first detector circuit comprises the first amplifier and the second amplifier, the mixing circuit acquires the first amplification signal and the second amplification signal, the first end of the first comparator receives the first amplification signal, the second end of the first comparator receives the second amplification signal, and the second detector circuit further comprises:
a second comparator, provided with a first end receiving a reference signal, a second end connected to the first end or the second end of the first comparator and receiving the first amplification signal or the second amplification signal, and an output connected to the first amplifier or the second amplifier, and configured to adjust amplitudes of the first amplification signal and the second amplification signal.

8. The adjustment circuit of claim 1, wherein the adjustment circuit further comprises:
a first turn-on circuit, provided with an input connected to an output of the first detector circuit, and an output connected to the impedance adjustment circuit, and configured to acquire the first detection signal and a first turn-on reference signal, so that the impedance adjustment circuit turns on or off adjustment of the impedance according to an output signal of the first turn-on circuit.

9. The adjustment circuit of claim 5, wherein the adjustment circuit further comprises:
a second turn-on circuit, provided with an input connected to the second detector circuit, and an output connected to the impedance adjustment circuit, and configured to acquire the second detection signal and a second turn-on reference signal, so that the impedance adjustment circuit turns on or off adjustment of the impedance according to an output signal of the second turn-on circuit.

10. The adjustment circuit of claim 1, wherein the adjustment circuit further comprises:
a processor circuit, provided with an input connected to the first detector circuit, and an output connected to the impedance adjustment circuit, and configured to adjust the impedance by the impedance adjustment circuit according to the first detection signal.

11. The adjustment circuit of claim 1, wherein the impedance adjustment circuit presets a plurality of impedance combinations, and the impedance adjustment circuit adjusts the impedance by traversal and/or table lookup.

12. The adjustment circuit of claim 1, wherein the impedance adjustment circuit and the aperture tuning circuit are integrated into the same module.

13. The adjustment circuit of claim 1, wherein the impedance adjustment circuit comprises:
a first branch, provided with a first end connected to the sampling circuit, and a second end which is grounded;
a second branch, provided with a first end connected to the aperture tuning circuit, and a second end which is grounded; and
a third branch, provided with a first end and a second end connected to the first end of the first branch and the first end of the second branch respectively.

14. The adjustment circuit of claim 13, wherein at least one of the first branch, the second branch or the third branch is provided with a plurality of inductors and/or capacitors connected in parallel, and a switch is connected in series with at least one path of the parallel circuit.
